(19) United States
(12) Patent Application Publication
(10) Pub. No.: US 2026/0066217 A1
(43) Pub. Date: Mar. 5, 2026

(54) METHOD FOR SUBSTRATE PROCESSING

(71) Applicant: TEL Manufacturing and Engineering of America, Inc., Chaska, MN (US)

(72) Inventors: Rupali Nigote, Hillsboro, OR (US); Robert Heussner, Hillsboro, OR (US)

(21) Appl. No.: 18/816,532

(22) Filed: Aug. 27, 2024

(51) Int. Cl. H01J 37/24; H01J 37/08; H01J 37/305

(52) U.S. Cl. CPC H01J 37/243; H01J 37/08; H01J 37/3053; H01J 2237/24405; H01J 2237/24564

(57) ABSTRACT

A method for substrate processing includes performing a local substrate process with a processing beam or flux on a substrate disposed in a process chamber. The processing beam or flux is ionized with an ionization current. An output current of the processing beam or flux is measured while performing the local substrate process. The ionization current for the local substrate process is controlled by keeping a product of the measured output current with the ionization current within a tolerance of a set point for the product of the measured output current with the ionization current.

### TECHNICAL FIELD

The present invention relates generally to a system and method for semiconductor processing, and, in particular embodiments, to a system and method for an etch process.

### BACKGROUND

Generally, a semiconductor device, such as an integrated circuit (IC) is fabricated by sequentially depositing and patterning layers of dielectric, conductive, and semiconductor materials over a semiconductor substrate to form a network of electronic components and interconnect elements (e.g., transistors, resistors, capacitors, metal lines, contacts, and vias) integrated in a monolithic structure. Many of the deposition and etch steps used to form the constituent structures of semiconductor devices are performed using plasma processes. Plasma processing techniques include chemical dry etching (CDE) (e.g., plasma ashing), physical or sputter etching, reactive ion etching (RIE), plasma-enhanced CVD (PECVD), plasma-enhanced atomic layer etch (PEALE), and atomic layer deposition (PEALD).

At each successive technology node, the minimum feature sizes are shrunk to reduce cost by roughly doubling the component packing density. The demand for low cost electronics with high functionality has driven feature sizes down to a few nanometers. With lateral dimensions approaching the scale of molecules and atoms, plasma technology faces the challenge of fabricating very high aspect ratio structures with processes that can also meet the stringent precision, uniformity, stability, and repeatability required for IC manufacturing. Further innovations in plasma processing systems and methods may have to be made to overcome the hurdles in the path of successful semiconductor device manufacturing.

### SUMMARY

In accordance with an embodiment, a method for substrate processing includes: performing a local substrate process with a processing beam or flux on a substrate disposed in a process chamber, the processing beam or flux being ionized with an ionization current; while performing the local substrate process, measuring an output current of the processing beam or flux; and controlling the ionization current for the local substrate process by keeping a product of the measured output current with the ionization current within a tolerance of a set point for the product of the measured output current with the ionization current.

In accordance with another embodiment, a method for substrate processing includes: determining a target product of ionization current and beam current for achieving a desired etch rate; based on the target product of ionization current and beam current, setting an ionization current for ionizing a processing beam or flux; measuring the beam current from the ionized processing beam or flux; and adjusting the ionization current based on feedback from the measured beam current, the adjusting the ionization current bringing the product of the ionization current with the measured beam current within a tolerance of the target product of ionization current and beam current.

In accordance with yet another embodiment, a system for local substrate processing includes: a process chamber, the process chamber including a substrate holder and an output current sensor, the output current sensor configured to measure an output current from a local substrate processing beam or flux; an ionization chamber coupled with the process chamber, the ionization chamber being configured to ionize the local substrate processing beam or flux with an input current before providing the local substrate processing beam or flux to the process chamber; and a controller coupled with the ionization chamber and the output current sensor, the controller being configured to: perform a local substrate process with the ionized local substrate processing beam or flux on a substrate disposed on the substrate holder; and while performing the local substrate process, controlling the input current with feedback from the output current sensor by holding a product of the input current and the measured output current within a tolerance of a target product of the input current and the output current.

It is to be understood that both the foregoing general description and the following detailed description are exemplary and explanatory only and are not restrictive of the disclosure, as claimed.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates a cross-sectional diagram of a local substrate processing system, in accordance with an embodiment;

FIG. 2 illustrates a flow chart diagram of a method for controlling a local substrate processing tool, in accordance with an embodiment;

FIG. 3 illustrates a flow chart diagram of a method for controlling a local substrate processing tool, in accordance with an embodiment;

FIG. 4 illustrates a process flow chart diagram of a method for substrate processing, in accordance with some embodiments; and

FIG. 5 illustrates a process flow chart diagram of a method for substrate processing, in accordance with some embodiments.

Corresponding numerals and symbols in the different figures generally refer to corresponding parts unless otherwise indicated. The figures are drawn to clearly illustrate the relevant aspects of the embodiments and are not necessarily drawn to scale. The edges of features drawn in the figures do not necessarily indicate the termination of the extent of the feature.

### DETAILED DESCRIPTION OF ILLUSTRATIVE EMBODIMENTS

The making and using of various embodiments are discussed in detail below. It should be appreciated, however, that the various embodiments described herein are applicable in a wide variety of specific contexts. The specific embodiments discussed are merely illustrative of specific ways to make and use various embodiments, and should not be construed in a limited scope.

This application relates to methods of controlling a local substrate processing tool for a directional etch process. The advantages of using the described method may stem from the local substrate processing capability of the processing tool, which refers to a capability of controllably altering processing parameters locally. In other words, a controlled process parameter of a local substrate processing process may be a function of coordinates of a location on the surface of the substrate. This allows the surface preparation processes to adjust the process conditions dynamically to achieve a desired surface characteristic, such as a desired surface topography (e.g., planarity, divot, and bump) or distribution of surface adhesion energy (i.e., surface activation).

In some embodiments, the local substrate processing tool is a gas cluster beam tool. Gas cluster beams are used for various applications in semiconductor manufacturing. Gas cluster beams are generated when a pressurized gas expands adiabatically to form clusters. The gas clusters may then be ionized by a plasma electron gun (PEG), accelerated, and focused into a beam to produce volumetric etching of a wafer surface. In some embodiments, only a small percentage of gas cluster constituents (including atoms and/or molecules) are ionized (e.g., 1 to 3 cluster atoms are ionized out of every 1,000 cluster atoms) for the purpose of acceleration.

Input Current (IC, also referred to as ionization current for some embodiments) and Output Current (OC, also referred to as Beam Current (BC) for some embodiments) are two independent measurements of beam intensity that impact etch rate. Electron emission intensity from the plasma electron gun determines the gas cluster ionization level, which is measured as an input current that produces the ionization. The resulting gas cluster beam intensity is also monitored quantitatively as an output current (also referred to as beam current), such as by using a Faraday box or cup mounted behind the wafer plane. Input current and output current are thus two independent measurements of beam intensity that may impact etch rate. The input current directly influences the output current, and both input current and output current correlate with the resulting etch rate of the beam. As the plasma electron gun ages, the relationship between input current, output current, and etch rate may change, making it difficult to maintain a stable etch rate over time using constant output current (such as beam current) or input current control (which may control ionization of the beam) methods.

According to one or more embodiments of the present disclosure, a control algorithm that uses both input current (IC) and output current (OC) by holding the product of input current with output current (IC*OC) constant provides significantly improved etch rate stability over the lifetime of a plasma electron gun. The control algorithm using a constant product of IC and OC was developed by analysis of etch rate data versus input and output current time trends. Disclosed embodiments include algorithms for finding and holding constant a set point for the product of input current with output current to achieve a desired etch rate and systems configured to use the algorithms for etch processes.

Although the described embodiments have used gas cluster beam (GCB) as examples of local substrate processes, it is understood that persons skilled in the art may apply the methods described in this disclosure to develop similar local substrate processes using some other local surface preparation technique using a processing beam or flux such as electron beam, ion beam (e.g., a monoatomic ion beam), cluster beam, or plasma torch processing with corresponding input current and output current parameters. The particle flux may be generated using radio frequency (RF) plasma, microwave plasma, DC electric field, or a gas nozzle.

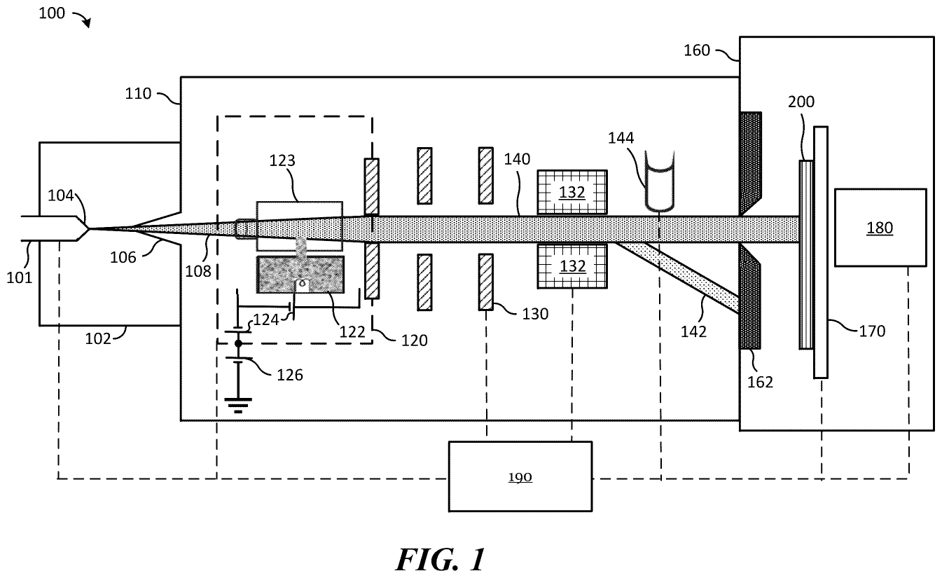

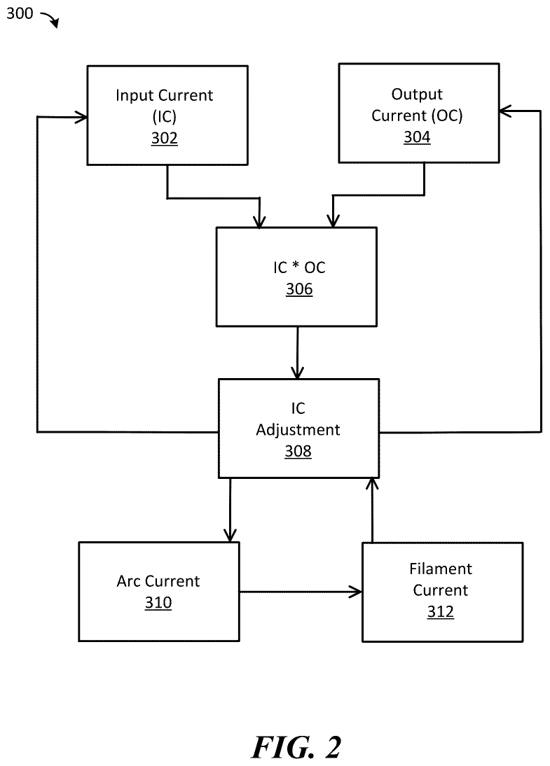

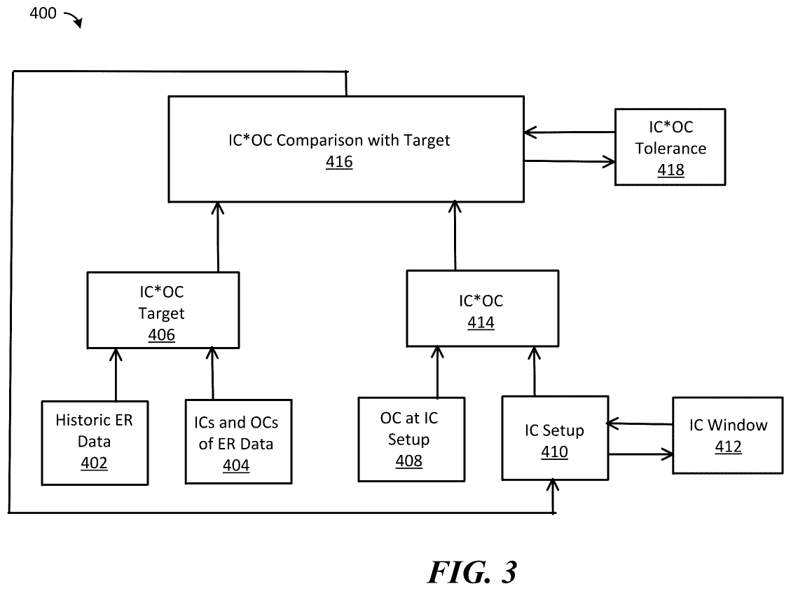

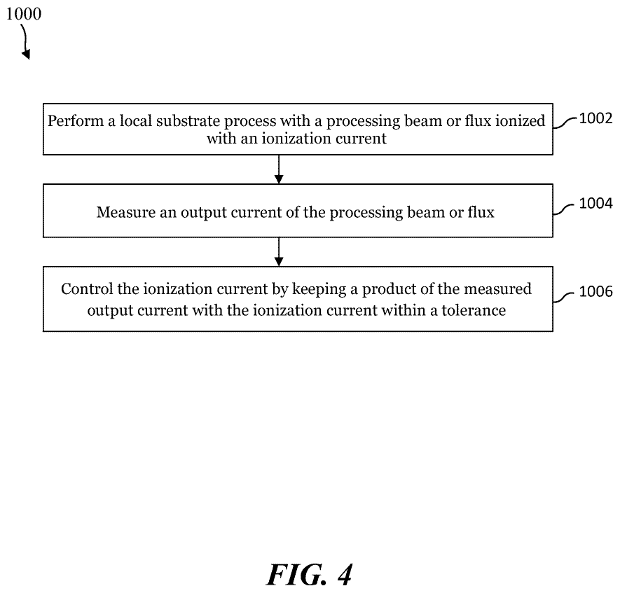

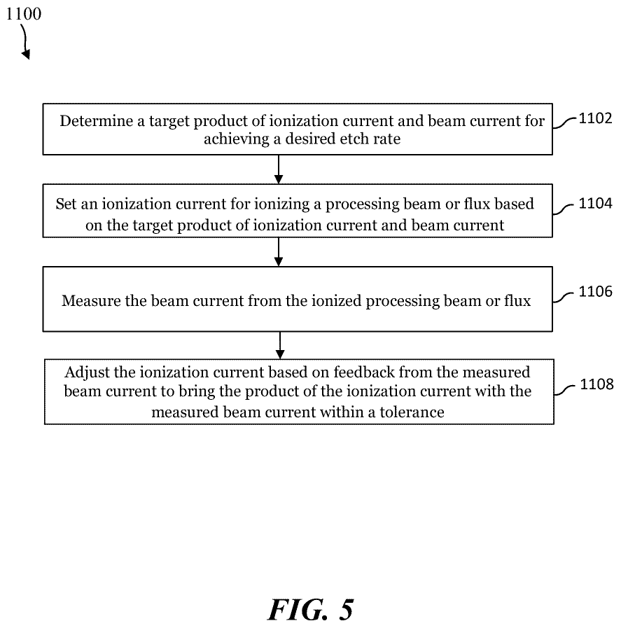

Embodiments of the disclosure are described in the context of the accompanying drawings. An embodiment of a local substrate processing system will be described using FIG. 1. Embodiments of methods for controlling a local substrate processing tool will be described using FIGS. 2 and 3. Embodiments of methods for substrate processing will be described using FIGS. 4 and 5.

FIG. 1 illustrates a cross-sectional diagram of an example local substrate processing system 100, in accordance with some embodiments. Although the local substrate processing system 100 as illustrated by FIG. 1 is a gas cluster beam system, it is understood that persons skilled in the art may apply the methods described in this disclosure for algorithms holding a product input current and output current parameters constant with some other local surface preparation system such as electron beam, ion beam (e.g., a monoatomic ion beam), or plasma torch processing. FIG. 1 illustrates the local substrate processing system 100 with the top side of the local substrate processing system 100 and the bottom side of the local substrate processing system 100 on the right of FIG. 1. The local substrate processing system 100 comprises a nozzle chamber 102, an ionization chamber 110, and a process chamber 160.

As illustrated by FIG. 1, the nozzle chamber 102 comprises a gas inlet 101, a nozzle 104, and a skimmer 106. The entire nozzle chamber 102 is maintained under vacuum conditions by a vacuum system (not illustrated). This vacuum is advantageous for the formation and preservation of gas clusters. The various gas pressures in the local substrate processing system 100, including the nozzle chamber 102, the ionization chamber 110, and the process chamber 160, are controlled by the vacuum system. As known to persons skilled in the art, a vacuum system may comprise various components such as high pressure gas canisters, valves (e.g., throttle valves), pressure sensors, gas flow sensors, vacuum pumps, pipes, and electronically programmable controllers. The nozzle chamber 102 is enclosed by walls that separate it from the subsequent ionization chamber 110 and maintain the vacuum integrity.

The gas inlet 101 may be located on the top side of the nozzle chamber 102, illustrated as the left side in FIG. 1. A pressurized gas (for example, oxygen (O₂), nitrogen trifluoride (NF₃), the like, or a combination thereof) is introduced into the local substrate processing system 100 through the gas inlet 101. The nozzle 104 is coupled to the gas inlet 101 and is configured to accelerate and focus the incoming gas into a jet 108 (also referred to as a high-velocity jet, a gas jet, or a high-velocity jet of gas). In some embodiments, the nozzle 104 has a converging-diverging geometry to achieve supersonic flow.

The skimmer 106 is disposed on an opposite side of the nozzle chamber 102. The skimmer 106 is situated downstream from the nozzle 104 along the jet 108. In various embodiments, the skimmer 106 is a conical or knife-edged structure that intercepts the peripheral portion of the jet 108. The skimmer 106 is configured to collimate the jet 108 and remove excess gas molecules, which may be advantageous for maintain the vacuum in subsequent chambers (e.g., the ionization chamber 110 and the process chamber 160).

In some embodiments, the nozzle chamber 102 functions as described herein. High-pressure gas, such as in a range of 100 Torr to 760 Torr, is introduced through the gas inlet 101. The gas then expands rapidly through the nozzle 104, cooling adiabatically and forming clusters of gas molecules, referred to as gas clusters. The resulting jet 108 travels at high velocity towards the skimmer 106 while containing these gas clusters. The skimmer 106 selects the central portion of the jet 108, thereby allowing the jet 108 to pass through to the ionization chamber 110 while deflecting peripheral gas molecules. The vacuum system continuously removes excess gas to maintain a low-pressure environment necessary for cluster formation and beam propagation.

The ionization chamber 110 is coupled with the nozzle chamber 102 and is situated immediately downstream from the nozzle chamber 102 along the jet 108 while it is in operation. The ionization chamber 110 comprises an ionization system 120, extraction optics 130, analysis magnets 134, and a neutralizer 144. The vacuum system maintains a high vacuum in the ionization chamber 110 to reduce or prevent unwanted collisions and preserve the integrity of the gas clusters.

In various embodiments, the ionization system 120 comprises a plasma electron gun 122 (also referred to as an ionizer), a jet ionization chamber 123, an ionizer bias circuit 124, and an acceleration power supply 126. The plasma electron gun 122 is configured to ionize the jet 108 passing through the jet ionization chamber 123, such as with thermionic filaments. In various embodiments, the thermionic filaments of the plasma electron gun 122 are made of a material with a low work function, such as tungsten or lanthanum hexaboride. However, any suitable material may be used for the thermionic filaments. The thermionic filaments are heated to emit electrons through thermionic emission for ionization of the jet 108 (e.g., to ionize gas clusters of the jet 108). The ionizer bias circuit 124 is coupled with the thermionic filaments of the plasma electron gun 122 and an acceleration power supply 126 in order to provide voltage to bias the thermionic filaments and accelerate the emitted electrons towards the jet 108 and its gas clusters. The emitted electrons are accelerated towards the jet 108 by the applied electric field. These energetic electrons collide with the gas clusters of the jet 108 in the jet ionization chamber 123 and may cause ionization through electron impact ionization. The ionization process of the ionization system 120 is designed to ionize the gas clusters of the jet 108 while reducing fragmentation, thereby preserving large cluster sizes that may be advantageous for the beam's intended applications.

The ionizer bias circuit 124 and acceleration power supply 126 allow precise control over the electron energy through the input current (also referred to as the ionization current) to the plasma electron gun 122. This may be advantageous for improving the ionization process and controlling the charge state of the gas cluster ions of the jet 108. By adjusting the temperature of the thermionic filaments in the plasma electron gun 122 through the input current and bias voltages, a controller 190 (see below) coupled with the ionization system 120 can control the electron emission rate and, consequently, the ion beam current (also referred to as beam current or output current) of the jet 108.

The ionization chamber 110 further comprises extraction optics 130. In some embodiments, the extraction optics 130 (also referred to as extraction electrodes) are a series of electrodes (illustrated as vertical bars in FIG. 1) positioned after the ionization system 120 to extract and initially focus the ionized gas clusters of the jet 108 to form a gas cluster beam 140. The extraction optics 130 create an electric field that draws the newly formed ionized gas clusters of the jet 108 and form them into a gas cluster beam 140. The arrangement of the extraction optics 130 may initiate the focusing of the gas cluster beam 140, thereby preparing it for further manipulation in subsequent stages.

After being focused by the extraction optics 130, the gas cluster beam 140 passes through an analysis magnet 132, which may be used to remove ions other than gas cluster ions from the gas cluster beam 140. The analysis magnet 132 may be, for example, a toroidal electromagnet through which the gas cluster beam 140 passes. However, any suitable analysis magnet(s) 132 in any suitable arrangements and configurations may be used.

A neutralizer 144 may be present located near the end of the ionization chamber 110, such as near the gas cluster beam 140 after it passes the analysis magnet 132 and close to the aperture 162 through which the gas cluster beam 140 passes into the process chamber 160. Here's a detailed description of the neutralizer: The neutralizer 144 is illustrated as a loop in order to represent an electron source electron-emitting device. The neutralizer 144 may be used to provide electrons in order to neutralize positive charge on the gas cluster ions of the gas cluster beam 140, thereby converting them back into neutral clusters. This neutralization of the gas cluster beam 140 may be beneficial for certain applications, such as reducing charge-related effects when the beam impacts the target surface (e.g., charge accumulation that may damage or destroy devices), reducing electrostatic repulsion within the gas cluster beam 140 and thereby potentially improving beam focus, or allowing for specific types of surface interactions that require neutral species. The neutralizer 144 may work by emitting low-energy electrons that are captured by the positively charged cluster ions of the gas cluster beam 140 as they pass through or near the neutralizer 144. The degree of neutralization can probably be controlled by adjusting the electron emission current or the geometry of the neutralizer 144 relative to the path of the gas cluster beam 140.

In embodiments where the neutralizer 144 is present, it may allow the local substrate processing system 100 to produce either charged or neutral cluster beams as required for different applications. The neutralizer 144 may add electrons to the clusters without significantly altering their velocity or trajectory, thereby preserving the beam integrity and other characteristics of the gas cluster beam 140. In some embodiments, the neutralizer 144 is constructed from materials capable of efficient electron emission at low temperatures, such as alkaline earth metal alloys or rare earth hexaborides. The neutralizer 144 may be useful for expanding the versatility of the local substrate processing system 100 by allowing it to produce both charged and neutral cluster beams for a wider range of potential applications in surface modification, thin film deposition, or materials analysis.

In some embodiments, a monomer beam 142 is split from the gas cluster beam 140. Although FIG. 1 illustrates the monomer beam 142 being split from the gas cluster beam 140 after the gas cluster beam 140 passes the analysis magnet 132 and before the gas cluster beam 140 passes the neutralizer 144, the monomer beam 142 may also be split from the gas cluster beam 140 before the gas cluster beam 140 passes the analysis magnet 132 or after the gas cluster beam 140 passes the neutralizer 144. The monomer beam 142 may be formed from individual atoms or molecules of the gas cluster beam 140 (e.g., monatomic ions) that have not clustered or from clusters that have fragmented during the ionization process. The monomer beam 142 may be separated from the gas cluster beam 140 by a device (not illustrated) using differences in mass-to-charge ratio and velocity, as monomers, being lighter, are more easily deflected by electric fields. Monomers may have higher kinetic energy per atom compared to the larger, slower-moving gas clusters of the gas cluster beam 140, thereby contributing to the different trajectory of the monomer beam 142. The presence and characteristics of the monomer beam 142 can provide valuable information about the ionization and clustering processes of the local substrate processing system 100. For example, the separated monomer beam 142 can be used for diagnostic purposes, such as measuring total ionization efficiency or monitoring source stability.

Next, the gas cluster beam 140 exits the ionization chamber 110 and passes through the aperture 162 into the process chamber 160. As illustrated by FIG. 1, the process chamber 160 is the final stage of the local substrate processing system 100. In some embodiments, the process chamber 160 is on a bottom side of the local substrate processing system 100, below the ionization chamber 110 and the nozzle chamber 102. The process chamber 160 is where the gas cluster beam 140 interacts with a target material, thereby performing the intended process (e.g., surface modification, etching, deposition). The process chamber 160 comprises an aperture 162, a substrate holder 170, and an output current sensor 180. Like the rest of the local substrate processing system 100, the process chamber 160 operates under high vacuum produced by the vacuum system to maintain beam integrity and ensure controlled processing conditions. Although not illustrated by FIG. 1, the process chamber 160 may include access ports for substrate or sample loading and unloading and/or for in-situ process monitoring. The walls of the process chamber 160 provide shielding to contain scattered particles and maintain safe operating conditions.

The aperture 162 is located at the entrance of the process chamber 160 and may be used to shape and control the final beam profile of the gas cluster beam 140. The gas cluster beam 140 enters the process chamber 160 through the aperture 162 and impacts the substrate 200 on the substrate holder 170. The substrate holder 170 (e.g., a mechanically scanned platen) is configured to hold a substrate (e.g., the substrate 200) or target material. In some embodiments, the substrate holder 170 is moveable (e.g., in translations in or perpendicular to the plane of the substrate holder 170 or in rotations around an axis). The substrate holder 170 may include an ability to scan, which allows for uniform processing of larger areas. This mechanical scanning capability may enable uniform processing across the surface of the substrate 200, thereby compensating for any non-uniformities in the beam profile of the gas cluster beam 140.

The substrate 200 is provided, such as through an access port (no illustrated) of the process chamber 160, into the process chamber 160 and disposed on the substrate holder 170. In various embodiments, the substrate 200 may be a part of, or including, a semiconductor device, and may have undergone a number of steps of processing following, for example, a conventional process. The substrate 200 accordingly may comprise layers of semiconductors and/or device regions useful in various microelectronics. In one or more embodiments, the substrate 200 may is a silicon wafer or a silicon-on-insulator (SOI) wafer. In certain embodiments, the substrate 200 may comprise a silicon germanium wafer, silicon carbide wafer, gallium arsenide wafer, gallium nitride wafer or other compound semiconductor. In other embodiments, the substrate 200 comprises heterogeneous layers such as silicon germanium on silicon, gallium nitride on silicon, silicon carbon on silicon, or layers of silicon on a silicon or SOI substrate. In various embodiments, the substrate 200 is patterned or embedded in other components of the semiconductor device.

In some embodiments, the substrate 200 comprises a lithium-comprising layer that includes a top surface of the substrate 200. For example, in various embodiments the lithium-comprising layer comprises lithium tantalate (LiTaO₃), lithium niobate (LiNbO₃), the like, or a combination thereof. The lithium-comprising layer may be used for the manufacturing of one or more piezoelectric devices by using the piezoelectric effect to convert electrical energy into mechanical motion or vice versa, as the lithium-containing material may have advantageous piezoelectric properties such as high electromechanical coupling coefficients and stable temperature behavior. It may be advantageous to trim or etch the lithium-containing material with a gas cluster beam process.

The process chamber 160 further comprises an output current sensor 180, which may be positioned below and/or beside the substrate holder 170. The output current sensor 180 is an instrument used for output current (in other words, beam current) measurements and dose control of the gas cluster beam 140. In some embodiments, the output current sensor 180 is a Faraday cup, which is a metal (conductive) cup configured to catch charged particles in vacuum or near vacuum. The resulting current can be measured and used to determine the number of ions or electrons hitting the Faraday cup. The output current sensor 180, in conjunction with the scanning mechanism of the substrate holder 170, allows for precise control of the ion dose delivered to the substrate 200. The output current sensor 180 may provide real-time feedback on beam characteristics of the gas cluster beam 140 (e.g., the measured output current or beam current), allowing for process adjustments based on, for example, holding constant a product of the measured output current with the input current delivered to the ionization system 120.

The local substrate processing system 100 further comprises a controller 190 to control local substrate processing and adjust parameters in real time. In some embodiments, the controller 190 is a programmable processor, microprocessor, computer, or the like. Although the controller 190 is illustrated as a single element for illustrative purposes, the controller 190 may include additional elements or be part of a single element. The controller 190 may be programmable by instructions stored in software, firmware, hardware, or a combination thereof. The controller 190 may be coupled to the gas inlet 101, the ionization system 120 (including the ionizer bias circuit 124 and the acceleration power supply 126), the extraction optics 130, the neutralizer 144, the device configured to divert the monomer beam 142, the output current sensor 180, the substrate holder 170, one or more sensors in the process chamber 160 configured for in-situ process monitoring of processes (e.g., etching processes or the like) performed on the substrate 200, and/or the vacuum system of the local substrate processing system 100. As such, the controller 190 may be configured to set, monitor, and/or control various control parameters associated with generating a local substrate processing beam or flux (e.g., an ionized gas cluster beam) and delivering ions to the surface of a microelectronic workpiece (e.g., a substrate 200 such as a semiconductor wafer). Control parameters may include, but are not limited to, gas flow rate, chamber pressure, input current (such as ionization current supplied to the ionization system 120), and output current (such as beam current measured by the output current sensor 180). Other control parameter sets may also be used.

FIG. 2 illustrates a flow chart diagram of a method 300 for controlling a local substrate processing tool (e.g., the local substrate processing system 100; see above, FIG. 1) using a product of input current (IC) 302 and output current (OC) 304, in accordance with some embodiments. The input current 302 is provided to the local substrate processing tool to ionize a local substrate processing beam or flux (e.g., a gas cluster beam 140; see above, FIG. 1). The input current 302 may also be referred to as an ionization current. The output current 304 of the local substrate processing beam or flux is measured quantitatively by, for example, an output current sensor 180 (see above, FIG. 1), such as a Faraday cup. The output current 304 may also be referred to as the beam current. The input current 302 and the output current 304 are provided to, for example, a controller 190 (see above, FIG. 1) as input parameters to control the process parameters of the local substrate processing beam or flux (e.g., the etch rate on a substrate 200; see above, FIG. 1).

The controller 190 then computes a product IC*OC 306 of the input current 302 times the output current 304. The controller 190 is configured to keep IC*OC 306 constant at a set value corresponding to a desired performance parameter (e.g., a desired etch rate). If IC*OC 306 is different from the set value, the controller 190 then performs an IC adjustment 308 of a setpoint of the input current 302. If, however, IC*OC 306 is not different from the set value by a desired tolerance (for example, a tolerance of ±0.5%, or a tolerance of ±0.2%), then no adjustment of the input current 302 is made. The resulting IC adjustment 308 of the input current 302 adjusts the setpoint of the arc current 310, which then results in an adjustment of the filament current 312 (such as current provided to thermionic filaments; see above, FIG. 1). The adjusted filament current 312 allows for the setpoint of the arc current 310 to be achieved and increases or decreases the ionization of the local substrate processing beam or flux (e.g., the gas cluster beam 140; see above, FIG. 1), thereby achieving the desired setpoint of the IC adjustment 308. The resulting output current 304 is then measured and provided, with the adjusted input current 302, to the controller 190 to compute another product IC*OC 306, and the cycle is repeated for any suitable number of cycles to complete a local substrate process (e.g., a directional etch). In some embodiments, the set value of IC*OC 306 and the input current 302 are adjusted during the process to produce a change in performance (e.g., an increased or decreased etch rate).

FIG. 3 illustrates a flow chart diagram of a method 400 for controlling a local substrate processing tool (e.g., the local substrate processing system 100; see above, FIG. 1) using a product of input current (IC) and output current (OC), in accordance with some embodiments. The method 400 (also referred to as an IC*OC algorithm) may be implemented in a computer such as the controller 190 (see above, FIG. 1). The method 400 begins with historic etch rate (ER) data 402 and corresponding input current (IC) and output current (OC) of the etch rate data 404, which is provided to the controller 190. Next, the controller 190 determines an input current times output current (IC*OC) target 406 based on a desired etch rate and using the historic etch rate (ER) data 402 and corresponding input currents (ICs) and output currents (OCs) of the etch rate data 404 as references.

The controller 190 may then begin operating the local substrate processing tool to produce a local substrate processing beam or flux (e.g., a gas cluster beam 140; see above, FIG. 1). The controller 190 performs an input current (IC) setup 410 to set the input current (IC) (e.g., the ionization current provided to thermionic filaments; see above, FIG. 1) to a desired value. The controller 190 further receives a measurement of the output current (OC) at the input current (IC) setup 408 that is measured quantitatively by, for example, an output current sensor 180 (see above, FIG. 1), such as a Faraday cup. The controller 190 may check if the input current is within a desired input current window 412 during the input current setup 410. If the input current is within the input current window 412, the controller 190 may proceed to the next step of calculating the product IC*OC 414. If the input current is outside the input current window 412, the controller 190 may adjust the input current to be within the input current window 412 or halt the process.

After the controller 190 computes IC*OC 414, the controller 190 performs an IC*OC comparison with target 416 by comparing IC*OC 414 with the IC*OC target 406. In some embodiments, this comparison comprises computing a comparison factor

$$1 - \frac{IC * {OC}_{measured} - IC * {OC}_{target}}{IC * {OC}_{measured}}$$

where IC*OC_{measured} is IC*OC 414 and IC*OC_{target} is the IC*OC target 406. However, any suitable comparison factor may be used. The comparison factor is then checked to see if it is within a set IC*OC tolerance 418. If the comparison factor is within the set IC*OC tolerance 418, the controller 190 continues performing the local substrate process until a next cycle of measurements and comparisons after a set time interval. If the comparison factor is outside the set IC*OC tolerance 418, the controller 190 returns to the IC setup 410 to adjust the input current, and the process is repeated. As such, this method 400 forms a closed-loop control system that continuously adjusts the input current to maintain the IC*OC product at the desired set point in order to achieve a desired performance (e.g., a desired etch rate).

The method 400 may operate in real-time by constantly monitoring and adjusting the process parameters to maintain a desired performance. By controlling the product of input current and output current, rather than either parameter individually, the algorithm may achieve more stable and consistent etch rates, such as throughout the lifetime of the plasma electron gun. This approach compensates for variations in the relationship between IC, OC, and etch rate that may occur as the PEG ages, potentially extending equipment lifespan and improving process reliability. For example, the method 400 may achieve a reduction in run-to-run etch rate variation of 60%.

FIG. 4 illustrates a process flow chart diagram of a method 1000 for substrate processing, in accordance with some embodiments. In step 1002, a local substrate process is performed with a processing beam or flux on a substrate disposed in a process chamber, as described above with respect to FIG. 1. The processing beam or flux is ionized with an ionization current. In step 1004, while performing the local substrate process, an output current of the processing beam or flux is measured, as described above with respect to FIGS. 2 and 3. In step 1006, the ionization current for the local substrate process is controlled by keeping a product of the measured output current with the ionization current within a tolerance of a set point for the product of the measured output current with the ionization current, as described above with respect to FIGS. 2 and 3.

FIG. 5 illustrates a process flow chart diagram of a method 1100 for substrate processing, in accordance with some embodiments. In step 1102, a target product of ionization current and beam current for achieving a desired etch rate is determined, as described above with respect to FIGS. 2 and 3. In step 1104, based on the target product of ionization current and beam current, an ionization current for ionizing a processing beam or flux is set, as described above with respect to FIGS. 2 and 3. In step 1106, the beam current from the ionized processing beam or flux is measured, as described above with respect to FIGS. 2 and 3. In step 1108, the ionization current is adjusted based on feedback from the measured beam current, as described above with respect to FIGS. 2 and 3. The adjusting the ionization current brings the product of the ionization current with the measured beam current within a tolerance of the target product of ionization current and beam current.

Example embodiments of the disclosure are summarized here. Other embodiments can also be understood from the entirety of the specification as well as the claims filed herein.
Example 1. A method for substrate processing, the method including: performing a local substrate process with a processing beam or flux on a substrate disposed in a process chamber, the processing beam or flux being ionized with an ionization current; while performing the local substrate process, measuring an output current of the processing beam or flux; and controlling the ionization current for the local substrate process by keeping a product of the measured output current with the ionization current within a tolerance of a set point for the product of the measured output current with the ionization current.
Example 2. The method of example 1, where the processing beam or flux is a gas cluster beam.
Example 3. The method of example 1, where the processing beam or flux is an ion beam.
Example 4. The method of one of examples 1 to 3, where the local substrate process is an etch process.
Example 5. The method of one of examples 1 to 4, where the tolerance is +0.5%.
Example 6. The method of one of examples 1 to 5, where the controlling the ionization current is performed in real time by a controller, the controller being configured to receive feedback from the measured output current.
Example 7. The method of one of examples 1 to 6, where the set point for the product of the measured output current with the ionization current is determined with historic etch rate data and corresponding ionization currents and output currents of the historic etch rate data.
Example 8. A method for substrate processing, the method including: determining a target product of ionization current and beam current for achieving a desired etch rate; based on the target product of ionization current and beam current, setting an ionization current for ionizing a processing beam or flux; measuring the beam current from the ionized processing beam or flux; and adjusting the ionization current based on feedback from the measured beam current, the adjusting the ionization current bringing the product of the ionization current with the measured beam current within a tolerance of the target product of ionization current and beam current.
Example 9. The method of example 8, where determining a target product of ionization current and beam current is performed using historic etch rate data and corresponding input currents and output currents of the historic etch rate data.
Example 10. The method of one of examples 8 or 9, where the processing beam or flux is a gas cluster beam.
Example 11. The method of one of examples 8 to 10, where measuring the beam current is performed with a Faraday cup.
Example 12. The method of one of examples 8 to 11, further including etching a substrate with the ionized processing beam or flux.
Example 13. The method of one of examples 8 to 12, where setting the ionization current includes checking if the ionization current is within a desired ionization current window.
Example 14. A system for local substrate processing, the system including: a process chamber, the process chamber including a substrate holder and an output current sensor, the output current sensor configured to measure an output current from a local substrate processing beam or flux; an ionization chamber coupled with the process chamber, the ionization chamber being configured to ionize the local substrate processing beam or flux with an input current before providing the local substrate processing beam or flux to the process chamber; and a controller coupled with the ionization chamber and the output current sensor, the controller being configured to: perform a local substrate process with the ionized local substrate processing beam or flux on a substrate disposed on the substrate holder; and while performing the local substrate process, controlling the input current with feedback from the output current sensor by holding a product of the input current and the measured output current within a tolerance of a target product of the input current and the output current.
Example 15. The system of example 14, where the local substrate processing beam or flux is a gas cluster beam.
Example 16. The system of example 15, further including a nozzle chamber coupled with the ionization chamber, the nozzle chamber being configured to provide a jet of gas clusters to the ionization chamber.
Example 17. The system of example 16, where the ionization chamber includes thermionic filaments, the thermionic filaments being configured to receive the input current and ionize the jet of gas clusters with arc current.
Example 18. The system of one of examples 14 to 17, where the output current sensor is a Faraday cup.
Example 19. The system of one of examples 14 to 18, where the local substrate process is a directional etch process.
Example 20. The system of one of examples 14 to 19, where the controller is further configured to determine the target product of the input current and output current using historic etch rate data and corresponding input currents and output currents of the historic etch rate data.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method for substrate processing, the method comprising:
performing a local substrate process with a processing beam or flux on a substrate disposed in a process chamber, the processing beam or flux being ionized with an ionization current;
while performing the local substrate process, measuring an output current of the processing beam or flux; and
controlling the ionization current for the local substrate process by keeping a product of the measured output current with the ionization current within a tolerance of a set point for the product of the measured output current with the ionization current.

2. The method of claim 1, wherein the processing beam or flux is a gas cluster beam.

3. The method of claim 1, wherein the processing beam or flux is an ion beam.

4. The method of claim 1, wherein the local substrate process is an etch process.

5. The method of claim 1, wherein the tolerance is ±0.5%.

6. The method of claim 1, wherein the controlling the ionization current is performed in real time by a controller, the controller being configured to receive feedback from the measured output current.

7. The method of claim 1, wherein the set point for the product of the measured output current with the ionization current is determined with historic etch rate data and corresponding ionization currents and output currents of the historic etch rate data.

8. A method for substrate processing, the method comprising:
determining a target product of ionization current and beam current for achieving a desired etch rate;
based on the target product of ionization current and beam current, setting an ionization current for ionizing a processing beam or flux;
measuring the beam current from the ionized processing beam or flux; and
adjusting the ionization current based on feedback from the measured beam current, the adjusting the ionization current bringing the product of the ionization current with the measured beam current within a tolerance of the target product of ionization current and beam current.

9. The method of claim 8, wherein determining a target product of ionization current and beam current is performed using historic etch rate data and corresponding input currents and output currents of the historic etch rate data.

10. The method of claim 8, wherein the processing beam or flux is a gas cluster beam.

11. The method of claim 8, wherein measuring the beam current is performed with a Faraday cup.

12. The method of claim 8, further comprising etching a substrate with the ionized processing beam or flux.

13. The method of claim 8, wherein setting the ionization current comprises checking if the ionization current is within a desired ionization current window.

14. A system for local substrate processing, the system comprising:
a process chamber, the process chamber comprising a substrate holder and an output current sensor, the output current sensor configured to measure an output current from a local substrate processing beam or flux;
an ionization chamber coupled with the process chamber, the ionization chamber being configured to ionize the local substrate processing beam or flux with an input current before providing the local substrate processing beam or flux to the process chamber; and
a controller coupled with the ionization chamber and the output current sensor, the controller being configured to:
perform a local substrate process with the ionized local substrate processing beam or flux on a substrate disposed on the substrate holder; and
while performing the local substrate process, controlling the input current with feedback from the output current sensor by holding a product of the input current and the measured output current within a tolerance of a target product of the input current and the output current.

15. The system of claim 14, wherein the local substrate processing beam or flux is a gas cluster beam.

16. The system of claim 15, further comprising a nozzle chamber coupled with the ionization chamber, the nozzle chamber being configured to provide a jet of gas clusters to the ionization chamber.

17. The system of claim 16, wherein the ionization chamber comprises thermionic filaments, the thermionic filaments being configured to receive the input current and ionize the jet of gas clusters with arc current.

18. The system of claim 14, wherein the output current sensor is a Faraday cup.

19. The system of claim 14, wherein the local substrate process is a directional etch process.

20. The system of claim 14, wherein the controller is further configured to determine the target product of the input current and output current using historic etch rate data and corresponding input currents and output currents of the historic etch rate data.
